(19) United States
(12) Patent Application Publication
(10) Pub. No.: US 2010/0296943 A1
(43) Pub. Date: Nov. 25, 2010

(54) Thermal barrier coated materilas, method of preparation thereof, and method of coating using them

(76) Inventors: Kee Sung Lee, Seoul (KR); Kyu Ick Jung, Seoul (KR); Sang Hyun Park, Seoul (KR); Jin-Hyon Lee, Gyeongsan-si (KR); Je-Hyun Lee, Seoul (KR); Yeon-Gil Jung, Changwon-si (KR); Ungyu Paik, Seoul (KR)

Correspondence Address: CHRISTIE, PARKER & HALE, LLP, PO BOX 7068, PASADENA, CA, 91109-7068, US

(21) Appl. No.: 11/919,808

(22) PCT Filed: Aug. 31, 2007
(86) PCT No.: PCT/KR2007/004218

§ 371 Date: Aug. 14, 2010

(30) Foreign Application Priority Data
Aug. 31, 2006 (KR) 10-2006-083410

(51) Int. Cl. F01D 5/14; C09D 1/00; C23C 16/00; B32B 15/04; B32B 18/00

(52) U.S. Cl. 416/241 R; 427/529; 427/576; 427/248.1; 428/469; 428/432; 106/286.2

(57) ABSTRACT

A sintered material for a thermal barrier coating is provided. The sintered material comprises Gd₂Zr₂O₇ doped with yttria (Y₂O₃). The sintered material exhibits excellent thermal barrier characteristics and has improved durability and high hardness. Therefore, the sintered material is used to form thermal barrier coatings on the surfaces of a variety of machine parts, thereby achieving high reliability and increased lifetime of the machine parts.

### TECHNICAL FIELD

The present invention relates to a sintered material for a thermal barrier coating (hereinafter, also referred to as a ‘sintered thermal barrier coating material’), a method for preparing the sintered material, and a method for forming a thermal barrier coating using the sintered material. More specifically, the present invention relates to a sintered material for a thermal barrier coating that exhibits excellent thermal barrier characteristics, improved durability and high hardness to provide high reliability and increased lifetime to machine parts when being applied to the machine parts, a method for preparing the sintered material, and a method for forming a thermal barrier coating using the sintered material.

### BACKGROUND ART

Engines for electric power generation may be excessively accelerated to achieve increased engine efficiency, causing an increase in the internal temperature of the engines. When engines are exposed to a high temperature atmosphere for a long period of time, metallic materials of the engines are prone to corrosion. This corrosion deteriorates the thermal and mechanical properties of the engines or causes contact damage when foreign fine particles collide with the metallic materials.

When gas turbine blades are vibrated, parts of the gas turbine blades are in contact with one another to cause stress to occur. Although this stress is not sufficient to allow the parts to be destroyed, it may induce occurrence of fatigue stress when the gas turbine blades are operated for a long period of time to cause serious damage to the parts.

Thermal barrier coatings are formed on the surfaces of metallic materials of engines and gas turbine blades to protect the metallic materials from exposure to high temperature for a long time and long-term fatigue stress. The necessity to form thermal barrier coatings is of particular importance because high temperatures are required to improve the thermal efficiency of engines.

Materials that exhibit superior heat insulating effects and mechanical properties are currently used for the formation of thermal barrier coatings. A thermal barrier coating must have a coefficient of thermal expansion similar to that of an underlying bond coat layer to prevent breakage resulting from the occurrence of stress caused due to the difference in coefficient of thermal expansion between the respective layers with increasing temperature.

Zirconia (ZrO₂) is most widely used among thermal barrier coating materials developed hitherto and has a relatively low conductivity when compared to other ceramic materials. Advantages of zirconia are good heat stability and very high coefficient of thermal expansion. However, pure zirconia undergoes phase transformation at elevated temperature. This phase transformation leads to a variation in the volume of the pure zirconia, resulting in a deterioration in the thermal conductivity characteristics of a thermal barrier coating formed using the pure zirconia. As a result, the thermal barrier coating is degraded.

Korean Patent Registration No. 390388 discloses a thermal barrier coating material composed of yttria (Y₂O₃)-stabilized zirconia (YSZ) in which the yttria is added as a stabilizer. As taught in the patent publication, a variation in volume arising from phase transformation of a thermal barrier coating formed using the coating material is inhibited due to the stabilization effects of the yttria. However, the stabilization effects are insufficient in a higher temperature atmosphere.

Coating materials having a pyrochlore crystal structure have been proposed in which at least one rare earth element selected from lanthanide elements, such as La, Nd, Sm and Gd, is added instead of yttria.

Korean Patent Publication No. 2005-115209 discloses a thermal barrier coating material having a pyrochlore structure in which IN₂O₃, Sc₂O₃ or Y₂O₃ is added to zirconia, hafnia and ceria. However, the thermal barrier coating material fails to exhibit satisfactory mechanical properties, for example, the surface of a coating formed using the coating material tends to be damaged by foreign fine particles.

On the other hand, in an attempt to replace the yttria-stabilized zirconia (YSZ) thermal barrier coating materials, Gd₂Zr₂O₇ is proposed in U.S. Ser. No. 09/164,700. However, there is a significant difference in coefficient of thermal expansion between Gd₂Zr₂O₇ and a base material (e.g., a heat resistant superalloy) because Gd₂Zr₂O₇ has a lower coefficient of thermal expansion than YSZ, and as a result, improvements in mechanical properties (e.g., hardness) and durability are insufficient.

### DISCLOSURE

### Technical Problem

It is a first object of the present invention to provide a sintered material for a thermal barrier coating that has high hardness and improved durability and exhibits excellent thermal barrier and thermal expansion characteristics.

It is a second object of the present invention to provide a method for preparing the sintered thermal barrier coating material.

It is a third object of the present invention to provide a method for forming thermal barrier coatings on the surfaces of a variety of machine parts as base materials by using the sintered material.

It is a fourth object of the present invention to provide a machine part having a thermal barrier coating formed by the method to achieve high reliability and increased lifetime.

### Technical Solution

In order to accomplish the first object of the present invention, there is provided a sintered material for a thermal barrier coating which comprises Gd₂Zr₂O₇ doped with yttria (Y₂O₃).

In an embodiment of the present invention, the yttria may be doped in an amount of 1.0 to 5.0% by weight, preferably 2.0 to 4.0% by weight and more preferably 2.2 to 3.6% by weight, based on the weight of the Gd₂Zr₂O₇.

In order to accomplish the second object of the present invention, there is provided a method for preparing yttria-doped Gd₂Zr₂O₇ as a sintered thermal barrier coating material, the method comprising the steps of mixing Gd₂O₃ with yttria-stabilized zirconia to obtain a mixed powder, pressing the mixed powder to obtain a pressed product, and sintering the pressed product.

In an embodiment of the present invention, the yttria-stabilized zirconia may contain 1.0 to 7.0 mol %, preferably 2.5 to 5.5 mol % and more preferably 3.0 to 4.7 mol % of yttria.

In order to accomplish the third object of the present invention, there is provided a method for forming a thermal barrier coating by coating the sintered thermal barrier coating material on a metal substrate.

A thermal barrier coating formed by the method has a columnar structure and contains yttria-doped Gd₂Zr₂O₇.

In order to accomplish the fourth object of the present invention, there is provided an engine, a gas turbine blade, a part of a system for electric power generation or a part of electric power machinery requiring heat resistance which comprises a thermal barrier coating formed by the method.

### Advantageous Effects

According to the present invention, the sintered thermal barrier coating material exhibits excellent thermal barrier and thermal expansion characteristics and has improved durability and high hardness. Therefore, the sintered thermal barrier coating material is used to form thermal barrier coatings on the surfaces of a variety of machine parts, thereby achieving high reliability and increased lifetime of the machine parts.

### DESCRIPTION OF DRAWINGS

FIG. 1 is a graph showing variations in the hardness of sintered thermal barrier coating materials prepared in Examples 1 and 2 and Comparative Examples 1 to 3 as measured by a micro-Vickers hardness test.

FIG. 2 is a scanning electron microscopy image (×20,000 magnification) of the surface of a thermal barrier coating formed in Example 5.

FIG. 3 is a scanning electron microscopy image (×5,000 magnification) of the fractured surface of a thermal barrier coating formed in Example 5.

### BEST MODE

Preferred embodiments of the present invention will now be described in greater detail.

The present invention provides a sintered material for a thermal barrier coating which comprises Gd₂Zr₂O₇ doped with yttria (Y₂O₃). The sintered thermal barrier coating material of the present invention can be used to form thermal barrier coatings on the surfaces of various articles due to its improved strength and hardness. The thermal barrier coating maintains the excellent physical properties even in a high temperature atmosphere required to enhance the efficiency of parts, such as engines, and exhibits superior resistance even under a fatigue load resulting from the collision of foreign fine particles or machine vibration to provide high reliability and increased lifetime to the parts.

Since Gd₂Zr₂O₇ exhibits excellent thermal properties and undergoes a small variation in volume caused by phase transformation at elevated temperature, little degradation is observed in a thermal barrier coating formed using Gd₂Zr₂O₇. However, poor mechanical properties (e.g., low hardness) of the thermal barrier coating are inevitable, resulting in an increased danger of damage to the surface of the coating by foreign fine particles.

The sintered thermal barrier coating material of the present invention is prepared by doping Gd₂Zr₂O₇ with yttria (Y₂O₃) to achieve improved mechanical properties, such as high hardness and good durability.

Specifically, when yttria is added to Gd₂Zr₂O₇, yttrium (Y) is doped on Zr sites of the Gd₂Zr₂O₇ texture, and as a result, more pores are formed to achieve lower thermal conductivity and improved strain resistance, thus contributing to the improvement of durability.

Particularly, when the sintered thermal barrier coating material of the present invention is used to form thermal barrier coatings on a variety of machine parts as base materials, nanovoids and nanopores are introduced into the thermal barrier coatings to increase the thermal properties of the thermal barrier coatings and function as mediators to solve the problem of heterogeneous coating compositions resulting from different vapor pressures of the respective elements. Furthermore, when the sintered thermal barrier coating material of the present invention is coated on a base material to form a thermal barrier coating, the degree of compaction of the columnar structure of the thermal barrier coating varies depending on the surface temperature of the base material. When the thermal barrier coating is exposed to a temperature higher than the coating temperature, the degree of compaction of the thermal barrier coating is further increased and the size of the Gd₂Zr₂O₇ crystal grains is increased.

The present invention also provides a method for preparing the sintered thermal barrier coating material, the method comprising the steps of mixing Gd₂O₃ with yttria-stabilized zirconia to obtain a mixed powder (S1), pressing the mixed powder to obtain a pressed product (S2), and sintering the pressed product (S3). The sintered thermal barrier coating material prepared by the method is highly porous. Additional sintering makes the sintered thermal barrier coating material more dense.

Specifically, in step (S1), Gd₂O₃ is mixed with yttria-stabilized zirconia in a weight ratio of 1:2 to 2:1 to obtain a mixed powder. At this time, the yttria content of the yttria-stabilized zirconia is varied control the amount of the yttria doped within the sintered material.

Particularly, the yttria-stabilized zirconia contains 1.0 to 7.0 mol %, preferably 2.5 to 5.5 mol % and more preferably 3.0 to 4.7 mol % of yttria. When the yttria is present in an amount of less than 1.0 mol %, no improvement in the durability and hardness of the sintered thermal barrier coating material can be expected. Meanwhile, when the yttria is present in an amount exceeding 7.0 mol %, an excessive amount of the yttria does not contribute to further improvements of durability and hardness and is thus uneconomical.

It is preferable that the Gd₂O₃ and the yttria-stabilized zirconia have a small particle diameter in view of high densification. The particle diameter of the Gd₂O₃ and the yttria-stabilized zirconia is more preferably from 0.01 to 10 μm and most preferably from 0.05 to 5 μm. Gd₂O₃ and yttria-stabilized zirconia having a particle diameter smaller than 0.01 μm suffer from difficulty in handling during processing steps, such as weighing and mixing. Meanwhile, Gd₂O₃ and yttria-stabilized zirconia having a particle diameter greater than 10 μm (i.e. a relatively small, specific surface area) causes a reduction in contact area between adjacent powder particles, making it difficult to achieve high densification.

The Gd₂O₃ and the yttria-stabilized zirconia may have various shapes, such as rods, plates, needles and spheres, but are not particularly limited to these shapes.

The mixing is performed using a common kneader by a dry or wet mixing process for 5-48 hours, preferably 16-24 hours. Representative examples of suitable kneaders include, but are not particularly limited to, mixers and ball mills.

In step (S2), the mixed powder is pressed to obtain a pressed product.

The pressing can be performed by any conventional technique. For example, the mixed powder is uniaxially pressed under a pressure of 50 MPa into a plate form.

In step (S3), the pressed product is sintered at different temperatures to prepare a sintered thermal barrier coating material in the form of an ingot and a densely packed sintered material for hardness evaluation according to the intended applications.

Specifically, the pressed product is sintered at ambient pressure in an oxidizing atmosphere, heated to 1,250-1,350° C. and thermally treated for 1-3 hours, preferably 2 hours.

The sintering allows gases present within the sintered material to be released into the atmosphere, leaving pores. Depending on the pressing and sintering temperature conditions, the sintered material has a porosity of about 30%.

A typical metal is slowly melted from its surface due to its small skin depth. In contrast, a typical ceramic material has a low electronic conductivity, which indicates a large skin depth. Accordingly, a sintered ceramic material is melted from its center upon being irradiated with electron beams and is thus susceptible to thermal impact. The sintered thermal barrier coating material of the present invention has a high porosity of 5-70%, preferably about 30%. As a result, the sintered thermal barrier coating material of the present invention has a lower thermal conductivity than densely packed sintered materials, thus ensuring better thermal impact resistance. If the sintered material of the present invention has a porosity higher than 70%, there is the danger that the efficiency of subsequent coating may be lowered.

It is preferred that a thermal barrier coating formed by the method of the present invention have a porosity of 5-70%, preferably about 30%. Below 5%, the thermal conductivity of the thermal barrier coating is not sufficiently lowered. Above 70%, there exists the danger that the mechanical properties (e.g., hardness) of the thermal barrier coating may be deteriorated.

The sintered thermal barrier coating material thus prepared is used to form a thermal barrier coating on the surface of a machine part.

The thermal barrier coating is formed by polishing and cleaning the surface of a base material and depositing the sintered thermal barrier coating material thereon.

Any metal or ceramic material that is used in a variety of machine parts may be used without limitation as the base material, and examples thereof include nickel-based superalloys, cobalt-based superalloys, iron alloys (e.g., steel), titanium alloys and copper alloys.

The deposition can be performed without limitation by any conventional technique known in the art. Representative deposition techniques are electron beam physical vapor deposition (EB-PVD), chemical vapor deposition (CVD), plasma vapor deposition (PVD), air plasma spray (APS), and low-pressure plasma spray (LPPS) techniques. Electron beam physical vapor deposition (EB-PVD) is preferred because it allows the coating to have a nanostructure. This is because the sintered thermal barrier coating material is coated by electron beam physical vapor deposition (EB-PVD) to form a thermal barrier coating having a columnar structure. The formation of a thermal barrier coating by electron beam physical vapor deposition will be explained in more detail below.

First, a base material is polished and washed. Thereafter, the surface of the washed base material is heated to 900° C., and then the sintered thermal barrier coating material is deposited thereon by electron beam physical vapor deposition under a pressure lower than 1×10⁻⁶ ton to form a thermal barrier coating. The thermal barrier coating has an anisotropic crystal structure, i.e. a unique columnar structure, to achieve improved peeling resistance. In addition, the columnar grains have a size in the nanometer range to provide improved heat stability to the thermal barrier coating. Furthermore, nanometer-sized pores are formed within and at the interfaces of the columnar grains to provide remarkable thermal barrier effects and excellent interfacial characteristics to the thermal barrier coating, contributing to improvements in the hardness and durability of the thermal barrier coating.

The thickness of the thermal barrier coating is not particularly restricted and may be varied depending on the kind and the intended application of the base material. The thermal barrier coating preferably has a thickness of 1 mm to 10 μm.

Even when the thermal barrier coating is used in a high temperature atmosphere for a long period of time, it exhibits superior resistance against thermal stress and fatigue failure resulting from a fatigue load caused by the collision of foreign fine particles or machine vibration due to the mutually independent columnar grains. Moreover, the thermal barrier coating formed by electron beam physical vapor deposition (EB-PVD) exhibits enhanced binding ability to base materials, compared to thermal barrier coatings formed by other deposition techniques.

As a result, although a variety of machine parts comprising the thermal barrier coating are used at high temperatures for a long period of time, high reliability and increased lifetime can be ensured. The kind of the machine parts is not limited. Representative examples of the machine parts include gas turbine blades used in electric power plants, parts of systems for electric power generation, parts of electric power machinery requiring heat resistance, and parts requiring thermal barrier coatings.

### Mode for Invention

Hereinafter, preferred embodiments are provided to assist in a further understanding of the invention. The following examples serve to provide further appreciation of the invention but are not meant in any way to restrict the scope of the invention.

### EXAMPLES

### Example 1

### Preparation of Sintered Thermal Barrier Coating Material and Sintered Material for Evaluation of Contact Damage Resistance

57.2% by weight of a Gd₂O₃ powder (diameter: 1.0 μm) and 42.8% by weight of an yttria-stabilized zirconia (YSZ) powder (diameter: 1.0 μm, yttria content: 3 mol %) were wet-mixed in a ball mill. The mixed powder was subjected to uniaxial pressing under 50 MPa to obtain a pressed product. Thereafter, the pressed product was sintered at 1,300° C. for 2 hours to prepare a sintered thermal barrier coating material (porosity: about 30%) in the form an ingot. The sintered material was further sintered at 1,600° C. for 2 hours to prepare another sintered material (porosity: ˜5%) for the evaluation of contact damage resistance. The doping concentration of the yttria in the yttria-doped Gd₂Zr₂O₇ was 229% by weight.

### Example 2

### Preparation of Sintered Thermal Barrier Coating Material and Sintered Material for Evaluation of Contact Damage Resistance

56.0% by weight of a Gd₂O₃ powder (diameter: 1.0 μm) and 44.0% by weight of an yttria-stabilized zirconia (YSZ) powder (diameter: 1.0 μm, yttria content: 4.56 mol %) were wet-mixed in a ball mill. The mixed powder was subjected to uniaxial pressing under 50 MPa to obtain a pressed product. Thereafter, the pressed product was sintered at 1,300° C. for 2 hours to prepare a sintered thermal barrier coating material (porosity: about 30%) in the form an ingot. The sintered material was further sintered at 1,600° C. for 2 hours to prepare another sintered material (porosity: ˜5%) for the evaluation of contact damage resistance. The doping concentration of the yttria in the yttria-doped Gd₂Zr₂O₇ was 3.52% by weight.

### Comparative Example 1

### Preparation of Sintered Thermal Barrier Coating Material and Sintered Material for Evaluation of Contact Damage Resistance

A sintered thermal barrier coating material and a sintered material for the evaluation of contact damage resistance were prepared in the same manner as in Example 1, except that a pure zirconia powder was used instead of the yttria-stabilized zirconia powder.

### Comparative Example 2

### Preparation of Sintered Thermal Barrier Coating Material and Sintered Material for Evaluation of Contact Damage Resistance

A sintered thermal barrier coating material and a sintered material for the evaluation of contact damage resistance were prepared in the same manner as in Example 1, except that YSZ (yttria content: 6.45% by weight) was used in an amount of 8 mol %.

### Comparative Example 3

### Preparation of Sintered Thermal Barrier Coating Material and Sintered Material for Evaluation of Contact Damage Resistance

A sintered thermal barrier coating material and a sintered material for the evaluation of contact damage resistance were prepared in the same manner as in Example 1, except that YSZ (yttria content: 8.25% by weight) was used in an amount of 10 mol %.

### Experimental Example 1

### Hardness Test

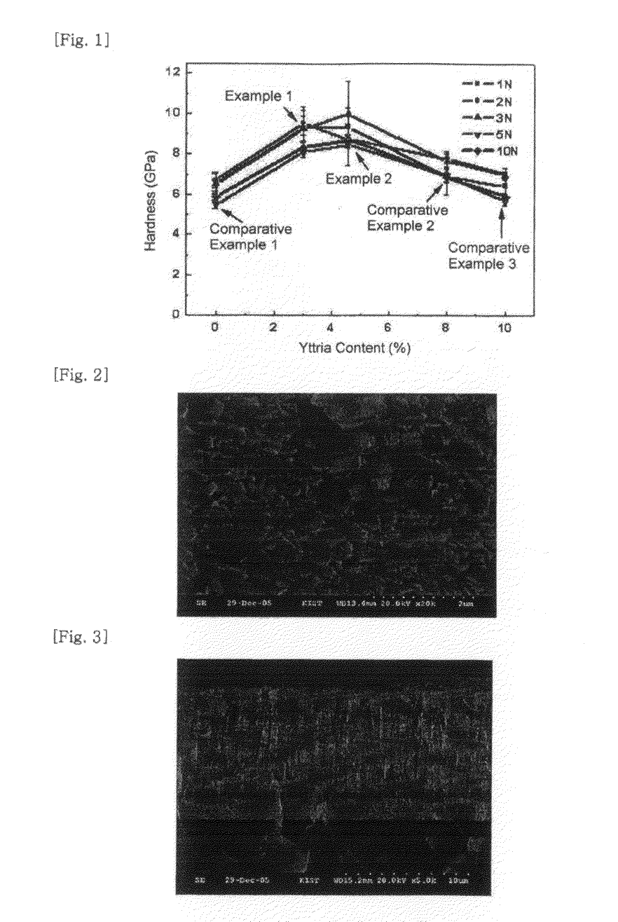

Each of the sintered materials for the evaluation of contact damage resistance, which were prepared in Examples 1 and 2 and Comparative Examples 1 to 3, was surface-polished and tested for hardness by a micro-Vickers indentation hardness test using a diamond indenter. The hardness of the sintered material was calculated using the size of the indentation and an applied load of 1-10 N. The obtained results are shown in Table 1 and FIG. 1.

TABLE 1

| Hardness | Indentation Load (N) | | | | |
|---|---|---|---|---|---|
| (GPa) | 1 | 2 | 3 | 5 | 10 |
| Example 1 | 9.29 | 9.54 | 9.25 | 8.11 | 8.34 |
| Example 2 | 9.34 | 8.73 | 9.99 | 8.49 | 8.70 |
| Comparative Example 1 | 6.61 | 6.68 | 6.54 | 5.49 | 5.88 |
| Comparative Example 2 | 6.89 | 7.77 | 7.67 | 6.93 | 6.88 |
| Comparative Example 3 | 6.43 | 7.04 | 6.96 | 5.66 | 5.89 |

As can be seen from the results of Table 1 and FIG. 1, there were slight differences in the hardness values depending on the applied loads, but the sintered materials prepared in Examples 1 and 2 had hardness values about 30% higher than those prepared in Comparative Examples 1 to 3. It is believed that the low hardness values of the sintered materials prepared in Comparative Examples 2 and 3 is due to a marked increase in the number of oxygen vacancies with increasing doping concentration of yttria.

### Example 3

### Formation of Thermal Barrier Coating

An alumina substrate was polished, cleaned and transferred to an EB-PVD system. The sintered thermal barrier coating material prepared in Example 1 was coated on the alumina substrate under a pressure of 1×10⁻⁶ toff and at a temperature of 900° C. by electron beam physical vapor deposition to form a thermal barrier coating.

### Example 4

### Formation of Thermal Barrier Coating

A thermal barrier coating was formed in the same manner as in Example 3, except that the sintered thermal barrier coating material prepared in Example 2 was used instead of the sintered thermal barrier coating material prepared in Example 1.

### Comparative Example 4

### Formation of Thermal Barrier Coating

A thermal barrier coating was formed in the same manner as in Example 3, except that the sintered thermal barrier coating material prepared in Comparative Example 1 was used instead of the sintered thermal barrier coating material prepared in Example 1.

### Comparative Example 5

### Formation of Thermal Barrier Coating

A thermal barrier coating was formed in the same manner as in Example 3, except that the sintered thermal barrier coating material prepared in Comparative Example 2 was used instead of the sintered thermal barrier coating material prepared in Example 1.

### Comparative Example 6

### Formation of Thermal Barrier Coating

A thermal barrier coating was formed in the same manner as in Example 3, except that the sintered thermal barrier coating material prepared in Comparative Example 3 was used instead of the sintered thermal barrier coating material prepared in Example 1.

### Experimental Example 2

### Analysis of Particles

The surfaces of the thermal barrier coatings formed by EB-PVD in Examples 3 and 4 and Comparative Examples 4 to 6 were observed under a scanning electron microscope.

FIG. 2 is a scanning electron microscopy image (×20,000 magnification) of the surface of the thermal barrier coating formed in Example 5, and FIG. 3 is a scanning electron microscopy image (×5,000 magnification) of the fractured surface of the thermal barrier coating formed in Example 5. Mutually individual columnar grains were observed in the thermal barrier coating formed in Example 5 (FIG. 2). As already explained, the peeling resistance of the thermal barrier coating can be improved by the columnar structure and the heat stability of the thermal barrier coating can be improved by the nanometer-sized columnar grains. In addition, nanometer-sized pores were formed within and at the interfaces of the columnar grains to provide remarkable thermal barrier effects and excellent interfacial characteristics to the thermal barrier coating, contributing improvements in the hardness and durability of the thermal barrier coating.

### Experimental Example 3

### Stress-Strain Analysis

The contact damage resistance of the thermal barrier coatings resulting from an applied load was evaluated in accordance with the following procedure.

The stress-strain relationships of the thermal barrier coatings formed in Examples 3 and 4 and Comparative Examples 4 to 6 were measured by the Hertzian indentation method using a spherical indenter. As the spherical indenter, a tungsten carbide (WC) sphere having a radius of 1.98-12.7 mm was used. The indention load was increased at intervals of 5N from an initial load (5N), 10N after 50N, 25N after 150N, and 50N after 400N until the coatings were broken. The indentation strain was expressed as the ratio between the indentation radius and the radius of the tungsten carbide sphere. The indentation stress was calculated by dividing the indentation load by the cross-sectional area of the indentation. The results are shown in Table 2.

TABLE 2

| | Stress (GPa) | | | | |
|---|---|---|---|---|---|
| Strain | | | Comparative | Comparative | Comparative |
| (%) | Example 3 | Example 4 | Example 4 | Example 5 | Example 6 |
| 0.03 | 1.92 | 2.10 | 1.64 | 1.65 | 1.78 |
| 0.06 | 4.36 | 4.54 | 3.49 | 3.08 | 4.00 |
| 0.07 | 5.11 | 5.39 | 4.44 | 4.91 | 4.88 |
| 0.08 | 5.93 | 6.29 | 5.03 | 5.75 | 5.68 |

From the results of Table 2, it, could be confirmed that the thermal barrier coatings containing yttria formed in Examples 3 and 4 and Comparative Examples 5 and 6 showed higher stress values than the thermal barrier coating containing no yttria formed in Comparative Example 4, as measured on the basis of the same strain. These results mean that the mechanical properties of the thermal barrier coatings were improved by the addition a the yttria to the Gd₂Zr₂O₇ structures. On the other hand, the thermal barrier coatings containing yttria in an optimum amount formed in Examples 3 and 4 had higher stress values than those containing an excess of yttria formed in Comparative Examples 5 and 6. These results represent that the thermal barrier coatings formed in Examples 3 and 4 showed excellent mechanical properties, such as good, damage resistance against load.

### Experimental Example 4

### Thermal Conductivity Measurement

The thermal conductivity values of the thermal barrier coatings formed in Examples 3 and 4 and Comparative Examples 4 to 6 were measured by the following procedure. First, the thermal diffusion coefficient of each of the thermal barrier coatings was measured using a laser flash apparatus (NETZSCH, LFA 427, Germany). A predetermined time after one side of the specimen was irradiated with laser, heat was transferred to the other side of the specimen. After a variation in the temperature of the specimen was measured using an infrared sensor, the thermal diffusion coefficient of the specimen was determined as a function of time. The measurements were repeated three times at the same temperature and the obtained values were averaged. The specific heat of the thermal barrier coating was measured using a differential scanning calorimeter (DSC). Based on the obtained data, the thermal conductivity of the specimen was measured at 1,000° C. by Equation 1:

k=a×ρ×Cp (1)

wherein k is the thermal conductivity of the specimen, a is the thermal diffusion coefficient, ρ is the density, and Cp is the specific heat.

The results are shown in Table 3.

TABLE 3

| | Thermal Conductivity (W/mK) | | | | |
|---|---|---|---|---|---|
| Temperature | | | Comparative | Comparative | Comparative |
| (° C.) | Example 3 | Example 4 | Example 4 | Example 5 | Example 6 |
| 1000 | 1.08 | 1.10 | 1.45 | 0.68 | 0.87 |

The thermal conductivity of yttria-stabilized zirconia (YSZ) between room temperature and 1,000° C. is an average of about 2.12 W/mK. The thermal barrier coating containing Gd₂Zr₂O₇ undoped with yttria formed in Comparative Example 4 had a thermal conductivity of 1.45 W/mK at 1,000° C. In contrast, the thermal barrier coatings formed in Examples 3 and 4 had a significantly low thermal conductivity of about 1.10 W/mK at 1,000° C., indicating superior thermal barrier performance. On the other hand, the thermal barrier coatings formed in Comparative Examples 5 and 6 had a thermal conductivity lower than 1 W/mK, indicating superior thermal barrier performance. However, the thermal barrier coatings formed in Comparative Examples 5 and 6 showed poor mechanical properties (e.g., low hardness) because the number of oxygen vacancies in the structures of the thermal barrier coatings was markedly increased, as demonstrated in Experimental Examples 1 and 2.

### Experimental Example 5

### Measurement of Coefficient of Thermal Expansion

The coefficients of thermal expansion of the sintered thermal barrier coating materials prepared in Examples 1 and 2 and Comparative Example 1 were measured at 1,000° C. using a dilatometer (L75, LINSEIS, Germany). The results are shown in Table 4.

TABLE 4

| Temperature | Coefficient of thermal expansion (10⁻⁶/° C.) | | |
|---|---|---|---|
| (° C.) | Example 1 | Example 2 | Comparative Example 1 |
| 1,000 | 10.0 | 9.65 | 8.7 |

Thermal stress is induced due to the difference in coefficient of thermal expansion between a metallic base material of a turbine blade and a ceramic thermal barrier coating material in a high temperature atmosphere. Therefore, the coefficient of thermal expansion is an important factor in selecting a thermal barrier coating material. A thermal barrier coating material must have a coefficient of thermal expansion similar to that of an underlying bond coat. YSZ has a relatively high coefficient of thermal expansion at 1,000° C. of about 10.9×10⁻⁶/° C., while other thermal barrier coating materials have a relatively low coefficient of thermal expansion. The results of Table 4 show that the thermal barrier coating materials prepared in Examples 1 and 2 had a coefficient of thermal expansion of about 10×10⁻⁶/° C., which is comparable to the coefficient of thermal expansion of YSZ. In contrast, the thermal barrier coating material prepared in Comparative Example 1 had a very low coefficient of thermal expansion of 8.7×10⁻⁶/° C. In view of the results, it is evident that the sintered thermal barrier coating materials prepared in Examples 1 and 2 showed excellent thermal expansion characteristics.

### INDUSTRIAL APPLICABILITY

As apparent from the foregoing, the sintered thermal barrier coating material of the present invention exhibits excellent thermal expansion and thermal barrier characteristics and superior mechanical properties (e.g., high hardness), thus satisfying the requirements for the physical properties of coating materials. Therefore, the sintered thermal barrier coating material of the present invention can be effectively applied to engines, gas turbine blades, parts of systems for electric power generation, and parts of electric power machinery requiring heat resistance.

1. A sintered material for a thermal barrier coating which comprises Gd₂Zr₂O₇ doped with yttria (Y₂O₃).

2. The sintered material according to claim 1, wherein the yttria is doped in an amount of 1.0 to 5.0% by weight, based on the weight of the Gd₂Zr₂O₇.

3. The sintered material according to claim 1, wherein the yttria is doped in an amount of 2.0 to 4.0% by weight, based on the weight of the Gd₂Zr₂O₇.

4. The sintered material according to claim 1, wherein the yttria is doped in an amount of 2.2 to 3.6% by weight, based on the weight of the Gd₂Zr₂O₇.

5. A method for preparing a sintered thermal barrier coating material, the method comprising the steps of:
mixing Gd₂O₃ with yttria-stabilized zirconia to obtain a mixed powder;
pressing the mixed powder to obtain a pressed product; and
sintering the pressed product.

6. The method according to claim 5, wherein the Gd₂O₃ is mixed with the yttria-stabilized zirconia in a weight ratio of 1:2 to 2:1.

7. The method according to claim 5, wherein the yttria-stabilized zirconia contains 1.0 to 7.0 mol % of yttria.

8. The method according to claim 5, wherein the yttria-stabilized zirconia contains 2.5 to 5.5 mol % of yttria.

9. The method according to claim 5, wherein the yttria-stabilized zirconia contains 3.0 to 4.7 mol % of yttria.

10. The method according to claim 5, wherein the sintered thermal barrier coating material has a high porosity of 5 to 70%.

11. A method for forming a thermal barrier coating by depositing the sintered thermal barrier coating material according to any one of claims 1 to 4 on the surface of a base material.

12. The method according to claim 11, wherein the deposition is performed by a technique selected from the group consisting of electron beam physical vapor deposition (EB-PVD), chemical vapor deposition (CVD), plasma vapor deposition (PVD), air plasma spray (APS), and low-pressure plasma spray (LPPS) techniques.

13. The method according to claim 11, wherein the deposition is performed by electron beam physical vapor deposition (EB-PVD).

14. A part comprising a base material and a thermal barrier coating formed on the surface of the base material wherein the thermal barrier coating is composed of the sintered material according to any one of claims 1 to 4.

15. The part according to claim 14, wherein the thermal barrier coating has a columnar structure.

16. The part according to claim 14, wherein the base material is a metal or ceramic.

17. The part according to claim 14, wherein the part is selected from the group consisting of engines, gas turbine blades, parts of systems for electric power generation, and parts of electric power machinery requiring heat resistance.
